(19) United States
(12) Patent Application Publication
(10) Pub. No.: US 2019/0081195 A1
(43) Pub. Date: Mar. 14, 2019

(54) Laminate Solar Concentrator

(71) Applicant: Heliac APS, Hørsholm (DK)

(72) Inventors: Henrik Pranov, Espergaerde (DK); Maria Matschuk, Bagsvaerd (DK)

(21) Appl. No.: 16/081,532

(22) PCT Filed: Mar. 2, 2017
(86) PCT No.: PCT/EP2017/054957

§ 371 Date: Aug. 31, 2018

(30) Foreign Application Priority Data
Mar. 2, 2016 (DK) PA201600133

(51) Int. Cl. H01L 31/054; F24S 23/30; F24S 23/70; G02B 19/00; G02B 5/09

(52) U.S. Cl. CPC H01L 31/0543; F24S 23/31; G02B 5/09; G02B 19/0023; G02B 19/0042; F24S 23/80

(57) ABSTRACT

A focusing polymer foil for use in forming an optical element for use in a solar concentrator, and an optical element for use in a solar concentrator, arranged such that the focusing polymer foil is removable in order to renew the function of the optical element following damage and/or wear to the focusing polymer foil due to environmental conditions. A method of repair of such a damaged optical element, and methods of making the focusing polymer foil and optical element.

### FIELD OF THE INVENTION

The present invention relates to an optical element for concentrating solar irradiation, and method and apparatus for manufacturing thereof.

### BACKGROUND OF THE INVENTION

In many optical applications, concentrators or lenses are used to focus light. Many types of lenses have been demonstrated, classical refractive lenses, concave reflector lenses, flat lenses etc. In the areas of Concentrated Solar Power (CSP) or Concentrated Photo Voltaics (CPV) in particular, the concentrators have failed to provide all the desired aspects, namely simultaneous precision, low weight, durability, large deflection angles, low energy loss, low maintenance costs, high durability and especially low cost.

WO2015/081961 describes an optical element for use as a linear solar concentrator, comprising a polymer foil with a lower Fresnel lens mirror structure and an optional upper antireflective layer, which greatly decreases internal losses found in typical Fresnel lens mirror structures. The optical element can be manufactured using roll-to-roll processes. It is envisaged that the optical element will be applied, for example by an adhesive, to the front side (ie the side from which light is incident on the element) of a plate substrate in use.

US2013/0312412 describes a solar-thermal concentrator for an expeditionary power generator system. The concentrator includes a collapsible dish assembly that is pivotably and tiltably mounted on a portable base assembly, where the dish assembly includes a reflector panel assembly including multiple flat, fan-shaped reflector panels that are secured to the frame and disposed in a semi-circular pattern. Each reflector panel includes multiple reflectors that collectively form a substantially flat Fresnelised reflective surface that redirects incident sunlight into a focal region. In order to reduce thickness and weight of the panels, they can comprise a silverised plastic film on plexiglass or moulded plastic. In another embodiment, the reflector is formed by multiple sheets of a polymer-film based reflective material that are placed as a stack (with removable adhesive between the layers) onto each reflector facet, which facets have been formed from stamped metal. An excessively dust-fouled reflector can be “refreshed” by removing the uppermost reflective material sheet (ie the uppermost sheet is peeled and discarded), exposing the high reflectivity surface of the layer below.

US2012/0037206 describes an improved solar concentrator in the form of a quasi-parabolic dish system comprising multiple identical mirrors, each constructed by adhering a flat sheet of mirror material, such as glass, to an appropriately shaped frame. Improvements in the cooling and electrical connection of photovoltaic cells are also described.

JP2013-167376 describes a low weight and easy to maintain solar concentration device comprising a light collection mirror having a linear Fresnel surface to collect incident solar light and a reflection membrane covering the linear Fresnel surface to reflect the incident solar light. These may be mounted on the back side of a light transmitting member, such as an injection moulded resin member, or on the front side of a member that need not be light transmissive. The latter arrangement is said to improve durability and reduce cost. In the former arrangement the reflection membrane may have a sealing layer thereon, such as EVA or PVA, to protect the light collection mirror from, for example, heat and humidity, and to assist in mounting it stably to a turntable by filling in any surface irregularities. It is stated that a flat-plate shaped Fresnel light collecting mirror makes maintenance such as cleaning and repair of the mirror surface easy compared with trough-type light collecting mirrors of the prior art, as the cleaning may be automated.

U.S. Pat. No. 4,315,671 describes a lens for concentration of electromagnetic radiation combining reflective and refractive properties. One embodiment has a substantially planar front surface (ie that on which light is incident) and inclined areas on the rear surface having a mirror coating. This allows direction of the reflected light both by the reflection angle imposed by the reflective inclined rear surface of the lens and by the refraction that takes place as a result of the passage of the reflected light through the body of the lens. The avoidance of mirror coated inclined surfaces on the front surface of the lens is said to make cleaning the lens easier.

U.S. Pat. No. 4,385,430 describes a focusing multi-point high-concentrator optical system useful for concentrating solar radiation and incorporating thin metallized Fresnel reflector elements applied to panels formed into focusing surfaces having a common axis. The Fresnel reflector elements are formed in transparent plastic materials by casting, moulding, extruding or embossing processes, followed by metallization of the grooved surface by well known methods, such as vacuum deposition. In order to prevent environmental damage to the transparent plastic materials, it is taught to provide a glass layer bonded by adhesive to the front (ie light-incident) face of the Fresnel reflector; it is also taught that to adhere the back face of the reflector to a substrate such as an aluminium sheet will reduce the cost of the assembly while maintaining the rigidity required.

U.S. Pat. No. 4,601,861 describes an apparatus and method for embossing a repeating pattern on to a sheet or laminate of transparent thermoplastic materials, comprising a continuous embossing tool in the form of a flexible metal belt or cylinder having on its outer surface an embossing pattern that is the reverse of the desired pattern. The embossing tool is continuously moved at a predetermined speed along a closed course through a heating station where its temperature is raised to above the glass transition temperature of the sheeting or laminate and a cooling station where its temperature is allowed to cool below the glass transition temperature of the sheeting or laminate. The sheeting is continuously moved into engagement with the embossing pattern on the tool and is pressed thereagainst until the sheeting is heated to above its glass transition temperature and subsequently cooled to below its glass transition temperature, at which time it is stripped from the tool and annealed in its patterned state. U.S. Pat. No. 6,972,103 similarly describes a calendaring process for shaping a heated plastic sheet.

In Concentrated solar Power (CSP) or Concentrated Photo Voltaic (CPV) applications, incident solar irradiation is focused by the means of a concentrator onto a solar receiver or solar cell, capable of transferring energy to a power generation system, typically using a thermal Rankine process or by photo voltaic processes. For CSP, In accordance with Carnot's law, the power generation process does in general become more effective if the solar receiver can be heated to higher temperatures. Typically, parabolic mirrors are used to reflect sunlight into the focal point of the parabola, in which the solar receiver is placed. However, due to the parabolic shape, there is a practical and economical limit of the width of the parabolic mirrors, which today is about 6-7 meters. Alternatively, reflectors using linear Fresnel lenses are used. Fresnel lenses have been known for a long time in the literature. Fresnel lenses consist of multiple discrete segments located in the same plane, but being tilted out-of-plane. There are two main types of Fresnel lens: imaging and non-imaging. Imaging Fresnel lenses use curved segments and produce sharp images, while non-imaging lenses use flat segments, and do not produce sharp images. For a thorough description of Fresnel lenses, see e.g. [1].

Fresnel lenses have been used in CSP applications, where large (on the order of centimeters to meters) free-space reflectors are tilted relative to a focal point with the purpose of maximizing the amount of collected solar irradiation. The reflectors typically consist of glass mirrors, where metal is evaporated onto one side of a glass plate. This approach typically results in relatively heavy constructions, with a weight on the order of 11 kg of steel and 18 kg of glass per square meter of reflector [2]. Polymers have been used for making low-weight elements, in many industries, among the solar industry. Typically PMMA plates with an embossed or extruded Fresnel pattern is used to focus the light. One challenge of using polymers is that they are susceptible to UV radiation. This can to some extent be reduced by the addition of UV stabilizers or UV blockers. However, these plates are relatively expensive, so if one could further reduce the cost and material usage of the focusing elements, this would be economically and environmentally desirable.

While certain of the prior art discussed above addresses the problem of providing for easy cleaning of optical elements in the context of solar concentrators, none addresses the problem of renewal of the efficiency of the optical elements once the lifetime of the element is exceeded, for example as a result of UV damage, damage by scratching from windborne dust, and/or scratching resulting from repeated washing procedures.

### OBJECT OF THE INVENTION

Accordingly, the present inventors have aimed to develop optical elements having replaceable functional elements, in order that the damaged parts of the optical elements can be renewed once their useful lifetime is exceeded, and methods of repairing such optical elements.

It may be seen as an object of the invention to provide an improved method for maintaining solar concentrators by industrial polymer foil made by industrial roll-to-roll manufacturing processes.

It may be seen as a further object of the invention to reduce cost of solar concentrators.

It may be seen as a further object of the invention to provide a planar solar concentrator where the focusing part is inexpensive and may be easily replaced.

It may be seen as a further object of the invention to simplify the construction of the solar field, ie the construction of the parts of a solar concentrator that collect incident irradiation.

It may be seen as a further object of the invention to enhance durability, simplify maintenance and reduce barriers towards replacement of the solar concentrators.

It may be seen as an object of the invention to provide an improved method for producing large areas of solar concentrator foils at either a throughput rate larger than today's state-of-the-art, at a substantially lower cost than the cost associated with today's state-of-the-art processes.

It is a further object of the invention to provide an alternative to the prior art.

Accordingly, in a first aspect, the present invention provides an optical element for use as a solar concentrator, comprising:

a substrate, and

a focusing polymer foil which comprises a layer of switchable adhesive,

wherein the layer of switchable adhesive adheres the focusing polymer foil to the substrate.

Preferably, the focusing polymer foil further comprises a refractive lens, preferably a microstructured refractive lens, more preferably a Fresnel lens, suitably in the form of Fresnel microstructures, suitably wherein the focusing polymer layer comprises Fresnel microstructures arranged in a linear, radial or concentric pattern. In certain embodiments, the focusing polymer foil further comprises a reflective layer, preferably a metal layer, such as a silver layer or an aluminium layer. Where the polymer foil comprises Fresnel microstructures and a reflective layer, the reflective layer is preferably formed on the Fresnel microstructures. Preferably, a protective layer is formed on the reflective layer, which protective layer suitably protects the reflective layer from oxidation, humidity and/or mechanical damage. Preferably, the focusing polymer foil is flexible, more preferably capable of being rolled. Suitably, the focusing polymer foil further comprises a UV stabilizer. However, in certain embodiments, it is preferred that the focusing polymer foil does not comprise a UV stabiliser.

Preferably, the thickness of the said focusing polymer foil is less than 200 μm, more preferably less than 100 μm, even more preferably less than 50 μm and most preferably less than 30 μm.

In some embodiments, it is advantageous to form an antireflective coating on the focusing polymer foil.

Preferably, the switchable adhesive is one whose adhesion may be reduced by application of heat, a solvent, pressure or delaminating force, or a combination thereof.

Preferably, the substrate is planar. Preferably, the substrate is mechanically rigid. Suitably, the substrate is non-focusing, ie its properties do not contribute to the focusing effect of the focusing polymer foil.

In a preferred embodiment of the first aspect, the substrate is capable of transmitting light therethrough. In this embodiment, the substrate is preferably a glass substrate.

In particular, the present invention provides an optical element for use as a solar concentrator, comprising:

a substrate capable of transmitting light therethrough and having a front side intended to face the sun in use and a back side intended to face away from the sun in use, and

a focusing polymer foil which comprises a refractive lens layer and a layer of switchable adhesive,

wherein the layer of switchable adhesive adheres the focusing polymer foil to the back side of the substrate. In this embodiment in particular, it is found that it is unnecessary to provide a UV stabiliser in the focusing polymer layer, as the glass substrate provides the required degree of UV protection.

Preferably, the weight per area of said focusing polymer foil to that of said substrate is less than 5%, more preferably 3%, even more preferably less than 2%, even more preferably less than 1%, and even more preferably less than 0.5% and most preferably less than 0.2%.

Preferably, the optical element is made according to the method of the fifth aspect of the invention.

In a second aspect, the present invention provides a focusing polymer foil for use in an optical element for a solar concentrator, which comprises a layer of switchable adhesive and a refractivel lens layer.

Preferably, the focusing polymer foil is used in forming the optical element according to the first aspect of the invention. Preferably, the focusing polymer foil is used in the repair of a damaged optical element according to the third aspect of the invention. Preferably, the focusing polymer foil is produced according to the method of the fourth aspect of the invention.

Preferably, the refractive lens layer is a microstructured refractive lens layer, preferably a Fresnel lens layer, suitably in the form of Fresnel microstructures. In certain embodiments, the focusing polymer foil further comprises a reflective layer, preferably a metal layer, such as a silver layer or an aluminium layer. Where the polymer foil comprises Fresnel microstructures and a reflective layer, the reflective layer is preferably formed on the Fresnel microstructures. Preferably, a protective layer is formed on the reflective layer, which protective layer suitably protects the reflective layer from oxidation, humidity and/or mechanical damage. Preferably, the focusing polymer foil is flexible, more preferably capable of being rolled. Suitably, the focusing polymer foil further comprises a UV stabilizer. However, in certain embodiments, it is preferred that the focusing polymer foil does not comprise a UV stabiliser.

In some embodiments, it is advantageous to form an antireflective coating on the focusing polymer foil.

Preferably, the switchable adhesive is one whose adhesion is reduced by application of heat, a solvent, pressure or delaminating force, or a combination thereof.

Preferably, the thickness of the said focusing polymer foil is less than 200 μm, more preferably less than 100 μm, even more preferably less than 50 μm and most preferably less than 30 μm.

Suitably, the focusing polymer foil may further comprise a peelable layer in contact with the switchable adhesive layer, which peelable layer is peeled from the switchable adhesive layer to expose it prior to adhesion to the substrate when forming the optical element of the first aspect of the invention, or repairing an optical element according to the third aspect of the invention.

In a third aspect, the present invention provides a method of repairing an optical element for use as a solar concentrator, the method comprising:

providing a damaged optical element for repair, comprising a substrate and a damaged focusing polymer foil which comprises a refractive lens layer and a layer of switchable adhesive, wherein the layer of switchable adhesive adheres the damaged focusing polymer foil to the substrate;

applying conditions to the damaged optical element that reduce the adhesion of the damaged focusing polymer foil to the substrate;

removing the damaged focusing polymer foil from the substrate;

providing a replacement focusing polymer foil comprising a refractive lens layer and a layer of switchable adhesive;

applying the switchable adhesive layer to the substrate such that the replacement focusing polymer foil is adhered to the substrate by the layer of switchable adhesive;

thus forming a repaired optical element.

Preferably, the replacement focusing polymer foil is a focusing polymer foil according to the second aspect of the invention. Preferably, the damaged focusing polymer foil is a focusing polymer foil according to the second aspect of the invention. Preferably, the repaired optical element is an optical element according to the first aspect of the invention. Preferably, the damaged optical element is an optical element according to the first aspect of the invention.

Preferably, the conditions applied to the damaged optical element to reduce its adhesion to the substrate are selected from the group consisting of: heat, one or more solvents, pressure, delaminating force, or a combination of two or more thereof. Preferably, the switchable adhesive, under the conditions applied to the damaged optical element to reduce its adhesion to the substrate, adheres more strongly to the damaged focusing polymer foil than to the substrate. Preferably, removal of the damaged focusing polymer foil from the substrate is performed by peeling the damaged focusing polymer foil from the substrate. Optionally, the substrate may be cleaned after removal of the damaged focusing polymer film therefrom and before application of the replacement polymer film, suitably to remove any residual adhesive therefrom.

In a fourth aspect, the present invention provides a method of manufacturing a focusing polymer foil for use in an optical element for a solar concentrator, comprising:

forming a polymer film melt;

laminating the polymer film melt to a carrier foil while applying structuring to the polymer film melt in the form of Fresnel lens microstructures;

optionally metallizing the structured polymer film;

applying a layer of switchable adhesive to the optionally metallized structured polymer film.

In a fifth aspect, the present invention provides a method of manufacturing an optical element according to the first aspect of the invention, comprising:

providing a focusing polymer foil according to the second aspect of the invention, optionally manufactured according to the fourth aspect of the invention;

providing a substrate;

applying the switchable adhesive layer to the substrate such that the focusing polymer foil is adhered to the substrate by the layer of switchable adhesive.

### BRIEF DESCRIPTION OF THE FIGURES

The method and apparatus according to the invention will now be described in more detail with regard to the accompanying figures. The figures show one way of implementing the present invention and is not to be construed as being limiting to other possible embodiments falling within the scope of the attached claim set.

FIG. 1 shows a first embodiment of an optical element according to the invention.

FIG. 2 shows a second embodiment of an optical element according to the invention.

FIG. 3 shows a third embodiment of an optical element according to the invention.

### DESCRIPTION OF THE INVENTION

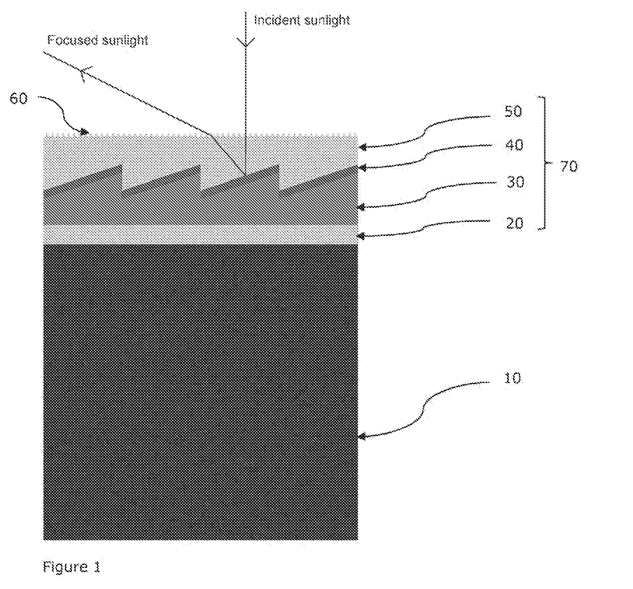

The present invention can be applied to three arrangements of optical element suitable for use in a solar concentrator. The first embodiment comprises a substrate to support the functional layers of the optical element, being the focusing polymer foil, which may comprise a refractive lens, such as a Fresnel lens and a reflective layer, for example by metallizing the side of the refractive lens furthest from the incident light in order to form a reflective back surface, and a layer of switchable adhesive that adheres the focusing polymer foil to the substrate. Such an arrangement is depicted in FIG. 1, which shows a cross section through an optical element of the first embodiment of the invention.

Referring to FIG. 1, the substrate 10 can be made from any material or materials that is/are capable of supporting the focusing polymer foil 70 of the optical element and can withstand the expected environmental conditions to which the optical element will be exposed. Accordingly, a material or materials capable of withstanding high temperatures and abrasion by dust and other particulates is suitable, and which is mechanically rigid, so that the optical element is not distorted and does not become misaligned with its intended focus point in use. As the substrate 10 is provided on the back side of the focusing polymer foil 70, ie on the opposite side of the focusing polymer foil 70 from the incident light, the substrate 10 need not be able to transmit light therethrough. The selection of suitable materials for the substrate 10 must also take into account the switchable adhesive to be used to adhere the focusing polymer foil 70 to the substrate, and in particular the conditions under which the switchable adhesive is to be treated in order to release the focusing polymer foil 70 from substrate 10. For example, where the adhesive is removable when heated, the substrate must withstand the necessary heating, for example at least to 80° C.; where the adhesive is to be softened by application of a solvent, the substrate must be inert to that solvent; and where the adhesive is pressure-sensitive, the substrate must be sufficiently robust to withstand the applied force without detriment to its ability to be re-used. Suitable materials include aluminium plate or glass plate. The thickness of the substrate 10 must be selected to ensure mechanical rigidity, and may suitably have a thickness of at least 2 mm, preferably at least 3 mm, such as from 3 to 6 mm, for example 4 mm, 5 mm or 6 mm. The size and shape of the substrate 10 will be dictated by the required size and construction of the solar concentrator into which the optical element is to be incorporated. In certain arrangements, the substrate may be non-planar, but preferably the substrate is planar. Suitably, the substrate maintains the geometry of the adhered focusing polymer film planar to the extent that it is still working as a focusing element. Planar focusing elements will have some tolerance to being non-planar, typically on the order of 0.5-2 degrees. Hence, the substrate preferably should not deviate more from a planar geometry than this during normal use of the concentrator.

The necessary functional structures to be included in this embodiment are the reflective layer 40 and a refractive lens 50. These are mounted in a removable fashion on the surface of the substrate 10 that is to face towards the light that will be incident on the solar concentrator.

The refractive lens 50, preferably a microstructured lens, such as a Fresnel lens is made from a material or materials that is/are able to transmit light therethrough, and which has/have a refractive index suitable to refract the light passing therethrough to a desired degree to attain the focusing effect of the lens. Suitably, the refractive lens 50 may be made of an optically transparent polymer or polymers (ie a plastics material or materials). For reasons of weight of the resulting optical element and lower brittleness, the use of a polymer or polymers is preferred. In a preferred embodiment, the refractive lens is made from a polymer foil, that is, a flexible sheet of polymer materials, comprising one or more layers of polymeric materials. Suitably, the polymer foil may contain non-polymeric parts, such as thin, reflective metal layers, UV stabilizers or other additives. Preferably, the polymer foil comprises one or more UV stabiliser to improve the life of the polymer foil in use. Suitable polymers for inclusion in the polymer foil layer are transparent polymers such as polymethylmethacrylate (PMMA), polyethylene (PE), polypropylene (PP)-polyethyleneterephthalate (PET) laminate or PET-Surlyn laminate. Suitably, the thickness of the polymer foil is less than 200 μm, more preferably less than 100 μm even more preferably less than 50 μm and most preferably less than 30 μm. The thinner the foil, the lower the material cost for replacement and the lower UV absorption will occur, and hence the more economical the plant comprising the solar concentrator will be, and hence a lower focusing element to supporting plate ratio is preferable, in terms of weight and/or thickness of the respective elements. Typically, a 4 mm thick glass substrate (supporting plate) will have a weight of 10 kg/m², whereas the focusing polymer foil will have a weight of 100-250 g/m². Thus, a weight ratio for focusing polymer foil:substrate would suitably be in the range 0.05 to 0.1, such as 0.06 to 0.075, or 0.07 to 0.05, preferably 0.01 to 0.025.

The polymer foil can be constructed in a known manner, such as is described in WO2015/081961. For example, due to the small thickness of the focusing polymer foil, it may be manufactured using standard roll-to-roll processes such as extrusion coating, where a carrier foil is laminated to a film melt which is being structured or coated using a structured cooling roller. The structured cooling roller may be manufactured using nickel sleeve technology, or by imprinting a pattern in an imprint layer on the surface of a conventional roller. The use of roll-to-roll processes, when compared to conventional casting or extrusion of thicker Fresnel elements, will have the potential to reduce the cost per square meter from the range of 100$ to the range of 1-2$ per square meter, similar to the cost of traditional packaging foils.

The refractive lens 50, when formed as a microstructured Fresnel lens, comprises Fresnel microstructures arranged in a linear, radial or concentric pattern. Fresnel microstructures are locally planar microstructures inclined at an angle relative to the macroscopic surface plane. There are two main types of Fresnel lens: imaging and non-imaging. Imaging Fresnel lenses use curved segments and produce sharp images, while non-imaging lenses use flat segments, and do not produce sharp images. See e.g. [1] for a thorough review and explanation about non-imaging Fresnel lenses. Linear Fresnel microstructures do not focus light in the direction parallel to the microstructure. Concentric or radial Fresnel microstructures focus light to a focal point.

The refractive lens 50 may preferably have an antireflective layer 60 on the non-structured face of the lens, which in this embodiment is the surface of the lens intended to face the incident light. The antireflective layer improves the efficiency of the solar concentrator, by allowing refraction to occur without high levels of internal reflection or reflection from the outer surface of the lens. The antireflective layer 60 may be a coating or structuring applied to the surface of refractive lens 50. Preferably, the antireflective layer 60 is a refractive index gradient antireflective layer, as these are almost independent of wavelength and incident angle. However, a multilayer dielectric antireflective layer film may also be used.

On the side of the refractive lens 50 bearing the Fresnel microstructures, a reflective layer 40 is provided. Typically, this is in the form of a thin metal foil, preferably a silver foil or an aluminum foil, and may be formed by evaporation or vapour deposition of the layer on to the Fresnel lens microstructures.

In order to protect the reflective layer 40 from wear, impacts, oxidation and/or environmental damage, such as due to humidity, it is preferred to provide a protective layer 30 over the reflective layer 40. The protective layer 30 is suitably a polymer (plastics) layer. A typical thickness for such a layer would be in the range 50 to 100 micrometers. Suitably, the layer may be applied by extrusion coating lamination or hot melt lamination. However, this layer is not an essential part of the optical element of the invention.

The functional layers 40, 50 of the optical element are mounted on the substrate 10 by a layer of switchable adhesive 20. By switchable adhesive is meant a substance that during use of the solar concentrator works as an adhesive, and that can be made less adhesive by subjecting the substance to a controlled outer condition, e.g. heat, pressure or a delamination force, or solvent, in order to remove the two adhered parts from each other. A suitable heat sensitive, or thermoplastic, adhesive is one that softens in order to allow the layers 30 (if present) 40 and 50 to be removed from the substrate 10 on heating to a temperature significantly above the usual operating temperature of a solar concentrator, such as a temperature of 80° C. Such adhesives include thermoplastic hot melt adhesives. A suitable pressure sensitive adhesive is one that is peelable from the substrate 10 under a force that is not sufficiently high to damage the surface of substrate 10 but is significantly higher than any force to which the optical element would be subjected to in normal use. Such adhesives include adhesives based on an elastomer compounded with a suitable tackifier, for example a rosin ester. Alternatively, the adhesive may be based on acrylics that have sufficient tack on their own and do not require a tackifier. Further options include bio-based acrylates, butyl rubber, ethylene-vinyl acetate (EVA) with high vinyl acetate content, natural rubber, nitriles, silicone rubbers with special tackifiers based on MQ silicate resins (MQ silicate resins are based on a monofunctional trimethylsilane (M) reacted with quadrafunctional silicon tetrachloride (Q)). A suitable solvent sensitive adhesive is one that softens or becomes peelable from the substrate on application of a solvent to which the optical element is not subjected in normal use and which does not cause damage to the substrate 10. For example, where the substrate is aluminium or glass, an acetone-sensitive or an MIBK-sensitive adhesive may be used. Solvent-sensitive adhesives include thermoplastic hot melt adhesives, and pressure-sensitive adhesives listed above that do not cross link. Regardless of the type of switchable adhesive used, it is preferred that the adhesive should have a higher degree of adherence to the functional elements 40, 50 than to the substrate 10, in order that, on peeling the functional layers 40, 50 away from the substrate 10, the adhesive is cleanly removed from the substrate 10 leaving it in a condition suitable for immediate application of a new set of functional layers 40, 50 thereto. Such adhesives include acrylate based pressure sensitive adhesives.

The total thickness of the polymer focusing element including the switchable adhesive (ie layers 20, 30, 40, 50 and 60 in FIG. 1, together forming focusing polymer foil 70) would suitably be in the range of 30-200 μm.

In use, incident sunlight is irradiated normal to the surface comprising an anti reflective layer 60, and is reflected at the boundary between the refractive lens 50 and reflective layer 40 to an angle (relative to normal) of twice the Fresnel element tilt angle, and subsequently refracted at the polymer-air transition, through the anti reflective layer. By controlling the tilt angle as a function of the lateral distance from the focal point, all incident sunlight can be focused. After some time in use, the functional elements 40, 50 will, as a result of environmental degradation such as exposure to UV light, scratching by dust abrasion, and/or oxidation, no longer be in a condition to perform their function to an acceptable degree of efficiency. At this time, the optical element is treated to cause the adhesive layer 20 to soften or become peelable from the substrate 10, and the functional layers 40, 50, along with the adhesive layer 20 and any other optional layers such as protective layer 30 and antireflective layer 60 (together forming focusing polymer foil 70), are removed from the substrate. A new focusing polymer foil 70, comprising functional layers 40, 50, along with the adhesive layer 20 and any other optional layers such as protective layer 30 and antireflective layer 60, may then be applied to the substrate 10, for example by a roll-to-plate process, in order that the optical element can be replaced in the solar concentrator, having improved or restored function.

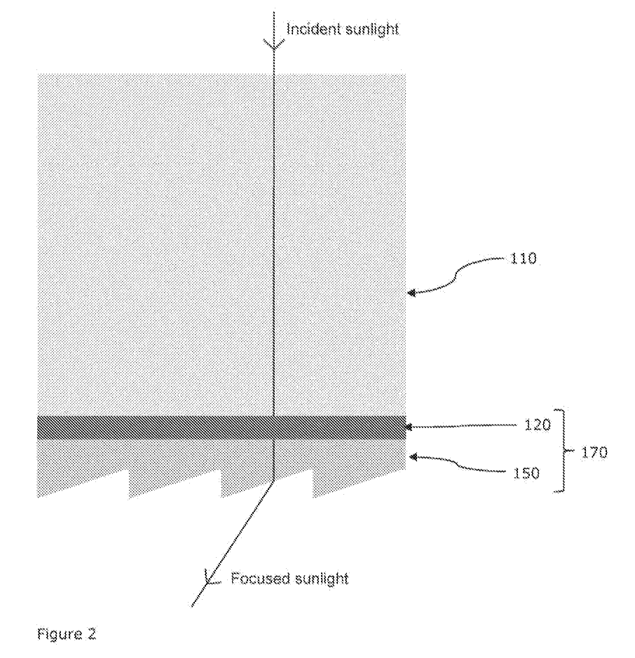

The second embodiment also comprises a substrate to support the functional layers of the optical element. This embodiment functions to focus light in a transmissive mode, in contrast to the reflective mode of the first embodiment. In this case, the functional layers comprise a focusing polymer foil 170 not comprising a reflective layer. A layer of switchable adhesive adheres the unstructured face of the Fresnel lens to the substrate. Such an arrangement is depicted in FIG. 2, which shows a cross section through an optical element of the second embodiment of the invention.

Referring to FIG. 2, the substrate 110 can be made from any material or materials that is/are capable of supporting the focusing polymer foil 170 of the optical element and can withstand the expected environmental conditions to which the optical element will be exposed. Accordingly, a material or materials capable of withstanding high temperatures and abrasion by dust and other particulates is suitable, and which is mechanically rigid, so that the optical element is not distorted and does not become misaligned with its intended focus point in use. As the substrate 110 is provided on the front side of the focusing polymer foil 170, ie on the side of the focusing polymer foil 170 from which light is incident, the substrate 110 must be able to transmit light therethrough. The selection of suitable materials for the substrate 110 must also take into account the switchable adhesive to be used to adhere the focusing polymer foil 170 to the substrate 110, and in particular the conditions under which the switchable adhesive is to be treated in order to release the focusing polymer foil 170 from substrate 110. For example, where the adhesive is removable when heated, the substrate must withstand the necessary heating, for example at least to 80° C.; where the adhesive is to be softened by application of a solvent, the substrate must be inert to that solvent; and where the adhesive is pressure-sensitive, the substrate must be sufficiently robust to withstand the applied force without detriment to its ability to be re-used. Preferably the material for the substrate is able to transmit light therethrough and absorbs or reflects UV light. Suitable materials include polymer (ie plastics material) or glass plate. Glass is a preferred material due to its inertness to UV degradation and its ability to shield polymer layers from short wavelength UV light. In addition, glass has a higher resistance to scratching than many polymers, and so a glass substrate is easier to clean and less likely to be damaged in a short time frame by cleaning or dust abrasion. Further, glass has good resistance to many solvents that may be used to soften the adhesive layer 120. The thickness of the substrate 110 must be selected to ensure mechanical rigidity, and may suitably have a thickness of at least 2 mm, preferably at least 3 mm, such as from 3 to 6 mm, for example 4 mm, 5 mm or 6 mm. The size and shape of the substrate 110 will be dictated by the required size and construction of the solar concentrator into which the optical element is to be incorporated. In certain arrangements, the substrate may be non-planar, but preferably the substrate is planar. Suitably, the substrate maintains the geometry of the adhered focusing polymer foil 170 planar to the extent that it is still working as a focusing element. Planar focusing elements will have some tolerance to being non-planar, typically on the order of 0.5-2 degrees. Hence, the substrate preferably should not deviate more from a planar geometry than this during normal use of the concentrator.

The substrate 110 may preferably have an antireflective layer on surface of the substrate intended to face the incident light, ie the opposite surface of the substrate from that on which the focusing polymer foil 170 is provided. The antireflective layer improves the efficiency of the solar concentrator, by reducing or preventing reflection from the outer surface of the lens. The antireflective layer may be a coating or structuring applied to the surface of substrate 110. Preferably, the antireflective layer is a refractive index gradient antireflective layer, as these are almost independent of wavelength and incident angle. However, a multilayer dielectric antireflective layer film may also be used.

The necessary functional structure to be included in this embodiment is the refractive lens 150. This is mounted in a removable fashion on the surface of the substrate 110 that is to face away from the light that will be incident on the solar concentrator, ie the back side of the substrate 110.

The refractive lens 150 is made from a material or materials that is/are able to transmit light therethrough, and which has/have a refractive index suitable to refract the light passing therethrough to a desired degree to attain the focusing effect of the lens. Suitably, the refractive lens 150 may be made of an optically transparent glass or an optically transparent polymer or polymers (ie a plastics material or materials). For reasons of weight of the resulting optical element and lower brittleness, the use of a polymer or polymers is preferred. In a preferred embodiment, the refractive lens is made from a polymer foil, that is, a flexible sheet of polymer materials, comprising one or more layers of polymeric materials.

Suitably, the polymer foil may contain non-polymeric parts, such as UV stabilizers or other additives. Preferably, the polymer foil comprises one or more UV stabilisers to improve the life of the polymer foil in use. Suitable polymers for inclusion in the polymer foil layer are transparent polymers such as polymethylmethacrylate (PMMA), polyethylene (PE), polypropylene (PP)-polyethyleneterephthalate (PET) laminate, or PET-Surlyn laminate. Suitably, the thickness of the polymer foil is less than 200 μm, more preferably less than 100 μm, even more preferably less than 50 μm and most preferably less than 30 μm. The thinner the foil, the lower the material cost for replacement and the lower UV absorption will occur, and hence the more economical the plant will be, and hence a lower focusing element to supporting plate ratio is preferable, in terms of weight and/or thickness of the respective elements. Typically, a 4 mm thick glass substrate (supporting plate) will have a weight of 10 kg/m², whereas the focusing polymer foil will have a weights of 100-250 g/m². Thus, a weight ratio for focusing polymer foil:substrate would suitably be in the range 0.05 to 0.1, such as 0.06 to 0.075, or 0.07 to 0.05, preferably 0.01 to 0.025.

The polymer foil 150 can be constructed in a known manner, such as is described in WO2015/081961. For example, due to the small thickness of the focusing polymer foil, it may be manufactured using standard roll-to-roll processes such as extrusion coating, where a carrier foil is laminated to a film melt which is being structured or coated using a structured cooling roller. The structured cooling roller may be manufactured using nickel sleeve technology, or by imprinting a pattern in an imprint layer on the surface of a conventional roller. The use of roll-to-roll processes, when compared to conventional casting or extrusion of thicker Fresnel elements, will have the potential to reduce the cost per square meter from the range of 100$ to the range of 1-2$ per square meter, similar to the cost of traditional packaging foils.

The refractive lens 150, when formed as a microstructured Fresnel lens, comprises Fresnel microstructures arranged in a linear, radial or concentric pattern. Fresnel microstructures are locally planar microstructures inclined at an angle relative to the macroscopic surface plane. There are two main types of Fresnel lens: imaging and non-imaging. Imaging Fresnel lenses use curved segments and produce sharp images, while non-imaging lenses use flat segments, and do not produce sharp images. See e.g. [1] for a thorough review and explanation about non-imaging Fresnel lenses. Linear Fresnel microstructures do not focus light in the direction parallel to the microstructure. Concentric or radial Fresnel microstructures focus light to a focal point.

The refractive lens 150 is mounted on the substrate 110 by a layer of switchable adhesive 120. By switchable adhesive is meant a substance that during use of the solar concentrator works as an adhesive, and that can be made less adhesive by subjecting the substance to a controlled outer condition, e.g. heat, pressure or a delamination force, or solvent, in order to remove the two adhered parts from each other. In this embodiment, it is essential that the switchable adhesive is one that can transmit light therethrough. A suitable heat sensitive, or thermoplastic, adhesive is one that softens in order to allow the layer 150 to be removed from the substrate 110 on heating to a temperature significantly above the usual operating temperature of a solar concentrator, such as a temperature of 80° C. Such adhesives include thermoplastic hot melt adhesives. A suitable pressure sensitive adhesive is one that is peelable from the substrate 110 under a force that is not sufficiently high to damage the surface of substrate 110 but is significantly higher than any force to which the optical element would be subjected to in normal use. Such adhesives include adhesives based on an elastomer compounded with a suitable tackifier, for example a rosin ester. Alternatively, the adhesive may be based on acrylics that have sufficient tack on their own and do not require a tackifier. Further options include bio-based acrylates, butyl rubber, ethylene-vinyl acetate (EVA) with high vinyl acetate content, natural rubber, nitriles, silicone rubbers with special tackifiers based on MQ silicate resins (MQ silicate resins are based on a monofunctional trimethylsilane (M) reacted with quadrafunctional silicon tetrachloride (Q)). A suitable solvent sensitive adhesive is one that softens or becomes peelable from the substrate on application of a solvent to which the optical element is not subjected in normal use and which does not cause damage to the substrate 110. For example, where the substrate is glass, an acetone-sensitive or an MIBK-sensitive adhesive may be used. Solvent-sensitive adhesives include thermoplastic hot melt adhesives, and pressure-sensitive adhesives listed above that do not cross link. Regardless of the type of switchable adhesive used, it is preferred that the adhesive should have a higher degree of adherence to the refractive lens 150 than to the substrate 110, in order that, on peeling the refractive lens 150 away from the substrate 110, the adhesive is cleanly removed from the substrate 110 leaving it in a condition suitable for immediate application of a new refractive lens 150 thereto. Such adhesives include acrylate based pressure sensitive adhesives.

The total thickness of the focusing polymer foil 170 (ie layers 120 and 150 in FIG. 2) would suitably be in the range of 30-200 μm.

In use, incident sunlight is irradiated normal to the surface of the substrate 110 on which the Fresnel lens 150 is not adhered, and passes through the substrate 110 and adhesive layer 120 into the Fresnel lens layer 150. On reaching the Fresnel microstructures on the back face of the Fresnel layer 150, the light is deflected to an angle (relative to normal) of twice the Fresnel element tilt angle, and refracted at the polymer-air transition. By controlling the tilt angle as a function of the lateral distance from the focal point, all incident sunlight can be focused. After some time in use, the Fresnel lens 150 will, as a result of environmental degradation such as exposure to UV light, scratching by dust abrasion, and/or oxidation, no longer be in a condition to perform its function to an acceptable degree of efficiency. At this time, the optical element is treated to cause the adhesive layer 120 to soften or become peelable from the substrate 110, and the Fresnel lens layer 150, along with the adhesive layer 120, is removed from the substrate. A new focusing polymer foil 170, comprising Fresnel lens layer 150, along with the adhesive layer 120, may then be applied to the substrate 110, for example by a roll-to-plate process, in order that the optical element can be replaced in the solar concentrator, having restored or improved function.

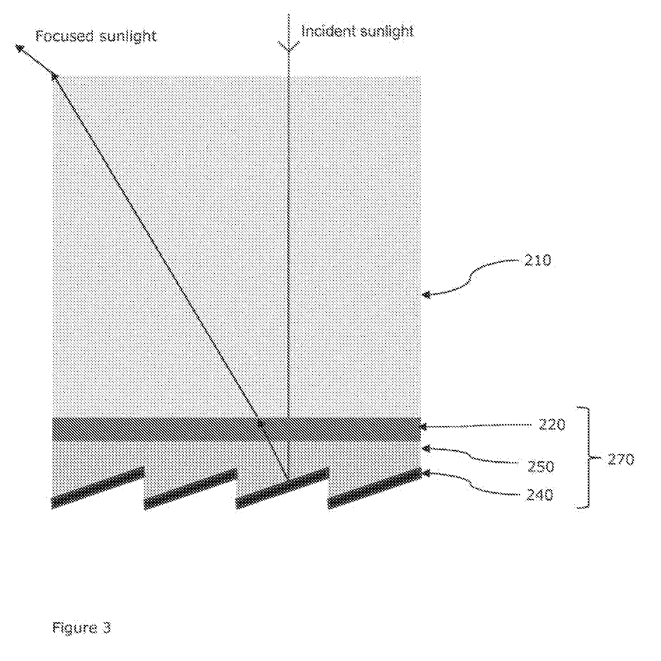

The third embodiment also comprises a substrate to support the functional layers of the optical element. In this case, the functional layers comprise a focusing polymer foil 270 comprising a reflective layer 240. A layer of switchable adhesive adheres the unstructured face of the refractive lens to the substrate. This embodiment functions to focus light in reflective mode, with the substrate providing further refraction of the light reflected from the back face of the optical element. Such an arrangement is depicted in FIG. 3, which shows a cross section through an optical element of the second embodiment of the invention.

Referring to FIG. 3, the substrate 210 can be made from any material or materials that is/are capable of supporting the focusing polymer foil 270 of the optical element and can withstand the expected environmental conditions to which the optical element will be exposed. Accordingly, a material or materials capable of withstanding high temperatures and abrasion by dust and other particulates is suitable, and which is mechanically rigid, so that the optical element is not distorted and does not become misaligned with its intended focus point in use. As the substrate 210 is provided on the front side of the focusing polymer foil 270, ie on the side of the focusing polymer foil 270 from which light is incident, the substrate 210 must be able to transmit light therethrough. The selection of suitable materials for the substrate 210 must also take into account the switchable adhesive to be used to adhere the focusing polymer foil 270 to the substrate 210, and in particular the conditions under which the switchable adhesive is to be treated in order to release the focusing polymer foil 270 from substrate 210. For example, where the adhesive is removable when heated, the substrate must withstand the necessary heating, for example at least to 80° C.; where the adhesive is to be softened by application of a solvent, the substrate must be inert to that solvent; and where the adhesive is pressure-sensitive, the substrate must be sufficiently robust to withstand the applied force without detriment to its ability to be re-used. Preferably the material for the substrate is able to transmit light therethrough and absorbs or reflects UV light. Suitable materials include polymer (ie plastics material) or glass plate. Glass is a preferred material due to its inertness to UV degradation and its ability to shield polymer layers from short wavelength UV light. In addition, glass has a higher resistance to scratching than many polymers, and so a glass substrate is easier to clean and less likely to be damaged in a short time frame by cleaning or dust abrasion. Further, glass has good resistance to many solvents that may be used to soften the adhesive layer 220. The thickness of the substrate 210 must be selected to ensure mechanical rigidity, and may suitably have a thickness of at least 2 mm, preferably at least 3 mm, such as from 3 to 6 mm, for example 4 mm, 5 mm or 6 mm. The size and shape of the substrate 210 will be dictated by the required size and construction of the solar concentrator into which the optical element is to be incorporated. In certain arrangements, the substrate may be non-planar, but preferably the substrate is planar. Suitably, the substrate maintains the geometry of the adhered focusing polymer foil 270 planar to the extent that it is still working as a focusing element. Planar focusing elements will have some tolerance to being non-planar, typically on the order of 0.5-2 degrees. Hence, the substrate preferably should not deviate more from a planar geometry than this during normal use of the concentrator.

The substrate 210 may preferably have an antireflective layer on surface of the substrate intended to face the incident light, ie the opposite surface of the substrate from that on which the focusing polymer foil 270 is provided. The antireflective layer improves the efficiency of the solar concentrator, by reducing or preventing reflection from the outer surface of the lens. The antireflective layer may be a coating or structuring applied to the surface of substrate 210. Preferably, the antireflective layer is a refractive index gradient antireflective layer, as these are almost independent of wavelength and incident angle. However, a multilayer dielectric antireflective layer film may also be used.

The necessary functional structure to be included in this embodiment is the refractive lens 250 and reflective layer 240. These are mounted in a removable fashion on the surface of the substrate 210 that is to face away from the light that will be incident on the solar concentrator, ie the back side of the substrate 210.

The refractive lens 250 is made from a material or materials that is/are able to transmit light therethrough, and which has/have a refractive index suitable to refract the light passing therethrough to a desired degree to attain the focusing effect of the lens. Suitably, the refractive lens 250 may be made of an optically transparent glass or an optically transparent polymer or polymers (ie a plastics material or materials). For reasons of weight of the resulting optical element and lower brittleness, the use of a polymer or polymers is preferred. In a preferred embodiment, the refractive lens is made from a polymer foil, that is, a flexible sheet of polymer materials, comprising one or more layers of polymeric materials. Suitably, the polymer foil may contain non-polymeric parts, such as thin, reflective metal layers, UV stabilizers or other additives. Preferably, the polymer foil comprises one or more UV stabilisers to improve the life of the polymer foil in use. Suitable polymers for inclusion in the polymer foil layer are transparent polymers such as polymethylmethacrylate (PMMA), polyethylene (PE), polypropylene (PP)-polyethyleneterephthalate (PET) laminate, or PET-Surlyn laminate. Suitably, the thickness of the polymer foil is less than 200 μm, more preferably less than 100 μm, even more preferably less than 50 μm and most preferably less than 30 μm. The thinner the foil, the lower the material cost for replacement and the lower UV absorption will occur, and hence the more economical the plant will be, and hence a lower focusing element to supporting plate ratio is preferable, in terms of weight and/or thickness of the respective elements. Typically, a 4 mm thick glass substrate (supporting plate) will have a weight of 10 kg/m², whereas the focusing polymer foil will have a weights of 100-250 g/m². Thus, a weight ratio for focusing polymer foil:substrate would suitably be in the range 0.05 to 0.1, such as 0.06 to 0.075, or 0.07 to 0.05, preferably 0.01 to 0.025.

The polymer foil 250 can be constructed in a known manner, such as is described in WO2015/081961. For example, due to the small thickness of the focusing polymer foil, it may be manufactured using standard roll-to-roll processes such as extrusion coating, where a carrier foil is laminated to a film melt which is being structured or coated using a structured cooling roller. The structured cooling roller may be manufactured using nickel sleeve technology, or by imprinting a pattern in an imprint layer on the surface of a conventional roller. The use of roll-to-roll processes, when compared to conventional casting or extrusion of thicker Fresnel elements, will have the potential to reduce the cost per square meter from the range of 100$ to the range of 1-2$ per square meter, similar to the cost of traditional packaging foils.

The refractive lens 250, when formed as a microstructured Fresnel lens, comprises Fresnel microstructures arranged in a linear, radial or concentric pattern. Fresnel microstructures are locally planar microstructures inclined at an angle relative to the macroscopic surface plane. There are two main types of Fresnel lens: imaging and non-imaging. Imaging Fresnel lenses use curved segments and produce sharp images, while non-imaging lenses use flat segments, and do not produce sharp images. See e.g. [1] for a thorough review and explanation about non-imaging Fresnel lenses. Linear Fresnel microstructures do not focus light in the direction parallel to the microstructure. Concentric or radial Fresnel microstructures focus light to a focal point.

The refractive lens 250 is mounted on the substrate 210 by a layer of switchable adhesive 220. By switchable adhesive is meant a substance that during use of the solar concentrator works as an adhesive, and that can be made less adhesive by subjecting the substance to a controlled outer condition, e.g. heat, pressure or a delamination force, or solvent, in order to remove the two adhered parts from each other. In this embodiment, it is essential that the switchable adhesive is one that can transmit light therethrough. A suitable heat sensitive, or thermoplastic, adhesive is one that softens in order to allow the layer 250 to be removed from the substrate 210 on heating to a temperature significantly above the usual operating temperature of a solar concentrator, such as a temperature of 80° C. Such adhesives include thermoplastic hot melt adhesives. A suitable pressure sensitive adhesive is one that is peelable from the substrate 210 under a force that is not sufficiently high to damage the surface of substrate 210 but is significantly higher than any force to which the optical element would be subjected to in normal use. Such adhesives include adhesives based on an elastomer compounded with a suitable tackifier, for example a rosin ester. Alternatively, the adhesive may be based on acrylics that have sufficient tack on their own and do not require a tackifier. Further options include bio-based acrylates, butyl rubber, ethylene-vinyl acetate (EVA) with high vinyl acetate content, natural rubber, nitriles, silicone rubbers with special tackifiers based on MQ silicate resins (MQ silicate resins are based on a monofunctional trimethylsilane (M) reacted with quadrafunctional silicon tetrachloride (Q)). A suitable solvent sensitive adhesive is one that softens or becomes peelable from the substrate on application of a solvent to which the optical element is not subjected in normal use and which does not cause damage to the substrate 210. For example, where the substrate is glass, an acetone-sensitive or an MIBK-sensitive adhesive may be used. Solvent-sensitive adhesives include thermoplastic hot melt adhesives, and pressure-sensitive adhesives listed above that do not cross link. Regardless of the type of switchable adhesive used, it is preferred that the adhesive should have a higher degree of adherence to the refractive lens 250 than to the substrate 210, in order that, on peeling the refractive lens 250 away from the substrate 210, the adhesive is cleanly removed from the substrate 210 leaving it in a condition suitable for immediate application of a new refractive lens 250 thereto. Such adhesives include acrylate based pressure sensitive adhesives.

The total thickness of the focusing polymer foil 270 (ie layers 220, 240 and 250 in FIG. 2) would suitably be in the range of 30-200 μm.

In use, incident sunlight is irradiated normal to the surface of the substrate 210 on which the refractive lens 250 is not adhered, and passes through the substrate 210 and adhesive layer 220 into the refractive lens layer 250. On reaching the reflective layer 240 on the back face of the refractive lens layer 250, the light is deflected to an angle (relative to normal) of twice the Fresnel element tilt angle, and refracted at the polymer-glass transition. By controlling the tilt angle as a function of the lateral distance from the focal point, all incident sunlight can be focused. After some time in use, the focusing polymer foil 270 will, as a result of environmental degradation such as exposure to UV light, scratching by dust abrasion, and/or oxidation, no longer be in a condition to perform its function to an acceptable degree of efficiency. At this time, the optical element is treated to cause the adhesive layer 220 to soften or become peelable from the substrate 210, and the refractive lens layer 250 and reflective layer 240, along with the adhesive layer 220, is removed from the substrate. A new focusing polymer foil 270, comprising refractive lens layer 250 and reflective layer 240, along with the adhesive layer 220, may then be applied to the substrate 210, for example by a roll-to-plate process, in order that the optical element can be replaced in the solar concentrator, having restored or improved function.

We have demonstrated that a very thin Fresnel micro-structured polymer foil can be made in high-throughput industrial processing using extrusion coating can be applied to a rigid mechanical support plate by the use of a switchable adhesive. This has been demonstrated in two configurations; one where the polymer foil has been metalized to form a reflective focusing Fresnel lens, where the foil is mounted on a planar aluminum or glass plate by the use of a thermoplastic adhesive, and the foil can be easily replaced by heating the plate to above 80 C, where the adhesive turns soft and the foil can be pulled of and recycled, while the support plate can be coated with a new piece of foil and reused in a solar plant. The other configuration comprises a transparent polymer foil with Fresnel lenses on the one side and a highly transmittant thermoplastic adhesive on the other. This is mounted on a support plate of planar float glass giving the adequate mechanical stability. By heating the glass to above 80 C the polymer foil can be taken of, and a new foil can be mounted, while the old foil can be recycled. The advantages of this is that more of the energy in the UV-range is transmitted, since glass has a lower absorbance of UV than e.g. acrylic plates, the need for UV blockers and stabilizers are eliminated, and the exterior of the concentrator may be easily and economically replaced in the case of scratches or other damages.

The invention and its use is sketched in FIG. 1.

Due to the small thickness of the focusing polymer foil, it may be manufactured using standard roll-to-roll processes such as extrusion coating, where a carrier foil is laminated to a film melt which is being structured or coated using a structured cooling roller. The structured cooling roller may be manufactured using nickel sleeve technology, or by imprinting a pattern in an imprint layer on the surface of a conventional roller. The use of roll-to-roll processes, when compared to conventional casting or extrusion of thicker Fresnel elements, will have the potential to reduce the cost per square meter from the range of 100$ to the range of 1-2$ per square meter, similar to the cost of traditional packaging foils.

The inventive step of the disclosed optical element is the combination of the very thin, and thereby efficient (not absorbing UV) and cheap (low material usage) micro Fresnel elements with the ability to replace these foils in a suitable way using a switchable adhesive on a planar substrate.

Furthermore, contributing to the inventiveness and especially the industrial applicability, all the processes for manufacturing and replacing the disclosed element may be performed in roll-to-roll or roll-to-plate setups, thereby significantly lowering the cost of the proposed element. Even further, the low cost of the roll-to-roll manufactured optical element makes it economically feasible to replace the foil when it is degraded by the environment, whereas parabolic trough mirrors or thick acrylic plate concentrators made of glass will be too expensive to replace and therefore suffer continuous reduction of efficiency as the mirror surface is degraded over time by abrasion from dust and other factors.

The invention furthermore relates to an optical element for use as a solar concentrator, comprising at least the following parts:
a planar, non-focusing mechanical rigid substrate,
a layer of switchable adhesive
a focusing polymer foil,
characterized by the said layer of switchable adhesive being switchable by external means
and characterized by the weight per area of said focusing polymer foil to that of said planar, non-focusing mechanical rigid substrate being less than 5%, more preferably 3%, even more preferably less than 2%, even more preferably less than 1% and even more preferably less than 0.5% and most preferably less than 0.2%.

The invention furthermore relates to an optical element where the said focusing polymer layer consists of a flexible polymer foil.

The invention furthermore relates to an optical element where the said focusing polymer layer comprises Fresnel microstructures arranged in a linear, radial or concentric pattern.

The invention furthermore relates to an optical element where the concentrated spot of solar irradiation is on the opposite side of the concentrator than the sun, and the said optical element is transparent.

The invention furthermore relates to an optical element where the concentrated spot of solar irradiation is on the same side of the concentrator than the sun, and the said layer of focusing polymer foil also comprises a layer of metal.

The invention furthermore relates to an optical element where the layer of switchable adhesive consists of a thermoplastic adhesive, and means for switching is heating of the optical element to at least 80 C.

The invention furthermore relates to an optical element where the layer of switchable adhesive consists of a solvent sensitive adhesive, and means for switching is exposure to solvent to the optical element.

The invention furthermore relates to an optical element where the thickness of the said focusing polymer layer is less than 200 μm, more preferably less than 100 μm even more preferably less than 50 μm and most preferably less than 30 μm.

The invention furthermore relates to an optical element where the solar concentration ratio is above 100, more preferably above 200, even more preferably above 300 and most preferably above 500.

The invention furthermore relates to an optical element where the focusing polymer foil comprises a UV stabilizer.

By polymer foil is meant a flexible sheet of polymer materials, comprising of one or more layers of polymeric materials. The polymer foil may contain non-polymeric parts, such as thin, reflective metal layers, UV stabilizers or other additives. The thickness of polymer foils is typically in the range of 20 to 200 μm, but thinner or thicker foils may be found.

By switchable adhesive is meant a substance that during use of the solar concentrator works as an adhesive, and that can be made less adhesive by subjecting the substance to a controlled outer condition, as e.g. heat or solvent, in order to remove the two adhered parts from each other.

By use of the solar concentrator is meant normal ambient conditions, where no organic solvents is present, temperatures are in the range of −40 C to +50 C and humidity levels are from 0 to 100%.

By non-focusing mechanical rigid substrate is meant a structure whose function solely is to keep the geometry of the adhered focusing element planar to the extent that it is still working as a focusing element. Planar focusing elements will have some tolerance to being non-planar, typically on the order of 0.5-2 degrees. Hence, the mechanical rigid substrate should not deviate more from a planar geometry than this during normal use of the concentrator.

By extrusion coating is meant the process of coating a foil in a continuous roll-to-roll process, as described in the literature, see e.g. [Gregory, B. H., “Extrusion Coating”, Trafford, 2007, ISBN 978-1-4120-4072-3].

By Fresnel structures is meant locally planar micro structures inclined at an angle relative to the macroscopic surface plane. There are two main types of Fresnel lens: imaging and non-imaging. Imaging Fresnel lenses use curved segments and produce sharp images, while non-imaging lenses use flat segments, and do not produce sharp images. See e.g. [1] for a thorough review and explanation about non-imaging Fresnel lenses.

By linear Fresnel lens microstructure is meant a Fresnel structure being linear or almost linear, thereby not focusing the light in the direction parallel to the microstructure.

By concentric or radial Fresnel lens microstructure is meant a Fresnel structure being circular or part-circular, thereby focusing the light in a common point.

All of the features described may be used in combination in so far as they are not incompatible therewith.

FIG. 1 shows a side view of a first embodiment of the optical element. Incident sunlight is irradiated normal to the surface, comprising an anti reflective layer, being deflected to an angle (relative to normal) of twice the Fresnel element tilt angle, and subsequently refracted at the polymer-air transition, through the anti reflective layer, and by controlling the tilt angle as function of the lateral distance from the focal point, all incident sunlight can be focused. The optical element may furthermore optionally have a supporting polymer backing laminated to the said reflective metal, whose main purpose is to prevent scratching and oxidation of the reflective metal layer. The focusing element is adhered to a stable substrate, e.g. a 3 mm aluminum plate using a thermoplastic adhesive which is switchable by increasing the temperature above normal operating conditions (e.g. above 80 C), allowing for easy replacement of the focusing foil.

FIG. 2 shows a side view of a second embodiment of the optical element. Incident sunlight is irradiated normal to the surface, comprising a float glass substrate, being e.g. 4 mm thick. On the opposite side of the float glass is adhered a focusing transmittive Fresnel lens polymer foil using a switchable adhesive which is switchable by increasing the temperature above normal operating conditions (e.g. above 80 C), allowing for easy replacement of the focusing foil.

We have demonstrated that a very thin Fresnel micro-structured polymer foil can be made in high-throughput industrial processing using extrusion coating. This can be applied to a rigid mechanical support plate by the use of a switchable adhesive. This has been demonstrated in two configurations; one where the polymer foil has been metalized to form a reflective focusing Fresnel lens, where the foil is mounted on a planar aluminum or glass plate by the use of an adhesive. The other configuration comprises a transparent polymer foil with Fresnel lenses on one side and a highly transmi adhesive on the other. This is mounted on a support plate of planar float glass giving the adequate mechanical stability. The advantages of this latter arrangement is that more of the energy in the UV-range is transmitted, since glass has a lower absorbance of UV than e.g. acrylic plates, the need for UV blockers and stabilizers are eliminated, and the exterior of the concentrator may be easily and economically replaced in the case of scratches or other damages.

In an embodiment, the switchable adhesive is a thermoplastic adhesive, and the foil can be easily replaced by heating the plate to above the softening temperature of the thermoplastic adhesive, suitably 80° C. as this temperature is significantly higher than the normal operating temperature reached by the optical element in use. Suitably, the heat is applied by an oven or by application of hot air, for example using a heat gun. Once the adhesive turns soft, the foil can be pulled off and recycled, while the support plate can be coated with a new piece of foil and reused in a solar plant.

### DETAILED DESCRIPTION OF AN EMBODIMENT

In one embodiment a steel cooling roller is coated with a metal master comprising a partly circular Fresnel lens made by single point diamond turning. This coated cooling roller is used to fabricate a transmittive polymer Fresnel foil using extrusion coating where a molten sheet of polypropylene is extruded onto a PET-carrier foil. Typical thicknesses of PET carrier foil is 12-75 μm and typical thickness of the PP coating is 30-60 μm. After generation of the focusing structures, a switchable thermoplastic adhesive is coated on the opposite side of the PET foil at elevated temperatures and protected with a non-adhesive liner, e.g. silicone paper. The foil can then be applied to a glass substrate using roll-to-plate lamination equipment. After a period of use, typically a few years, the quality of the focusing element will have been degraded due to UV degradation, scratches from dust and washing procedures and general weather exposure. Once it is deemed that the quality is too low, the optical concentrator is heated to 80 C, the old focusing foil is removed and recycled, and a new focusing foil is applied to the substrate, which is then reused as a solar concentrator. By this method, most of the concentrator can be made in robust and cheap materials, whereas only the focusing part needs to be made in more sensitive materials, thus greatly reducing maintenance costs of the solar plant, as only a small fraction of the solar concentrator needs to be replaced. A typical concentrator element would consist of a supporting plate being several (e.g. 3-6) mm thick to give mechanical stability, whereas the polymer focusing element including the switchable adhesive would be in the range of 30-200 μm, thus only representing a few percent or less of the total material consumption. The thinner the foil, the lower the material cost for replacement and the lower UV absorption will occur, and hence the more economical the plant will be, and hence a lower focusing element to supporting plate ratio is preferable.

Further aspects of the invention are set out in the following clauses:

1. An optical element for use as a solar concentrator, comprising at least the following parts:
a planar, non-focusing mechanical rigid substrate,
a layer of switchable adhesive
a focusing polymer foil,
characterized by the said layer of switchable adhesive being switchable by external means
and characterized by the weight per area of said focusing polymer foil to that of said planar, non-focusing mechanical rigid substrate being less than 5%, more preferably 3%, even more preferably less than 2%, even more preferably less than 1% and even more preferably less than 0.5% and most preferably less than 0.2%.

2. An optical element according to clause 1, where the said focusing polymer layer consists of a flexible polymer foil.

3. An optical element according to clause 1, where the said focusing polymer layer comprises Fresnel microstructures arranged in a linear, radial or concentric pattern.

4. An optical element according to clause 1, where the concentrated spot of solar irradiation is on the opposite side of the concentrator than the sun, and the said optical element is transparent.

5. An optical element according to clause 1, where the concentrated spot of solar irradiation is on the same side of the concentrator than the sun, and the said layer of focusing polymer foil also comprises a reflective layer of metal.

6. An optical element according to clause 1, where the layer of switchable adhesive consists of a thermoplastic adhesive, and means for switching is heating of the optical element to at least 80 C.

7. An optical element according to clause 1, where the layer of switchable adhesive consists of a solvent sensitive adhesive, and means for switching is exposure to solvent to the optical element.

8. An optical element according to clause 1 where the thickness of the said focusing polymer layer is less than 200 μm, more preferably less than 100 μm even more preferably less than 50 μm and most preferably less than 30 μm.

9. An optical element according to clause 1 where the solar concentration ratio is above 100, more preferably above 200, even more preferably above 300 and most preferably above 500.

10: An optical element according to clause 1 where the focusing polymer foil comprises a UV stabilizer.

### EXAMPLES

### Example 1

Two half-parts of a lens with dimensions 2200 mm×2800 mm and focal depth of 2200 mm is manufactured in a PET-Surlyn foil laminate, having a total thickness of 140 μm, resulting in a weight of approximately 160 g/m². The foil laminate is coated by a pressure sensitive adhesive and laminated to a 4 mm mechanically rigid float glass (having a weight of approximately 10 kg/m², thereby forming a stable optical element. The optical efficiency of the optical element is measured to 65%.

The stable optical element is mounted in a frame on a solar tracker. A water-based receiver is placed in the focal point absorbing the focused sunlight, thereby heating up the water, which is used for district heating.

After 3 years of use, the efficiency of the focusing part of the optical element (the foil laminate) has been lowered to 50% through weathering, abrasion and UV degradation. To restore the efficiency of the optical element, the focusing foil is being removed by applying a force to the foil, which removes both the foil laminate and the switchable adhesive from the glass. A new foil laminate is then adhered to the glass, reforming the optical element with an efficiency of 65%.

### Example 2

A lens with dimensions 1450 mm×1450 mm and focal depth of 2000 mm is manufactured in a PET-PP foil laminate, having a total thickness of 150 μm, resulting in a weight of approximately 170 g/m². The foil laminate is coated by a temperature sensitive adhesive and laminated to a 4 mm mechanically rigid float glass (having a weight of approximately 10 kg/m², thereby forming a stable optical element. The optical efficiency of the optical element is measured to 75%. The stable optical element is mounted in a frame on a solar tracker. A thermal oil-based receiver is placed in the focal point absorbing the focused sunlight, thereby heating up the thermal oil, which is used for combined heating and power generation.

After 3 years of use, the efficiency of the focusing part of the optical element (the foil laminate) has been lowered to 65% through weathering, abrasion and UV degradation. To restore the efficiency of the optical element, the focusing foil is being removed by heating it to 80 C and removing the foil, which removes both the foil laminate and the switchable adhesive from the glass. A new foil laminate is then adhered to the glass, reforming the optical element with an efficiency of 75%.

### Example 3

A reflective lens with dimensions 2200 mm×2800 mm and focal depth of 1200 mm is manufactured in a PET-PP-Aluminum foil laminate, having a total thickness of 300 μm, resulting in a weight of approximately 320 g/m². The foil laminate is coated by a solvent sensitive adhesive and laminated to a 5 mm mechanically rigid aluminum plate (having a weight of approximately 12 kg/m², thereby forming a stable optical element. The optical efficiency of the optical element is measured to 50%.

The stable optical element is mounted in a frame on a solar tracker. A thermal oil-based receiver is placed in the focal point absorbing the focused sunlight, thereby heating up the thermal oil, which is used for combined heating and power generation.

After 2 years of use, the efficiency of the focusing part of the optical element (the foil laminate) has been lowered to 35% through weathering, abrasion and UV degradation. To restore the efficiency of the optical element, the focusing foil is being removed by dipping it in acetone and removing the foil, which removes both the foil laminate and the switchable adhesive from the aluminum plate. A new foil laminate is then adhered to the aluminum plate, reforming the optical element with an efficiency of 50%.

Although the present invention has been described in connection with the specified embodiments, it should not be construed as being in any way limited to the presented examples. The scope of the present invention is set out by the accompanying claim set. In the context of the claims, the terms “comprising” or “comprises” do not exclude other possible elements or steps. Also, the mentioning of references such as “a” or “an” etc. should not be construed as excluding a plurality. The use of reference signs in the claims with respect to elements indicated in the figures shall also not be construed as limiting the scope of the invention. Furthermore, individual features mentioned in different claims, may possibly be advantageously combined, and the mentioning of these features in different claims does not exclude that a combination of features is not possible and advantageous.

All patent and non-patent references cited in the present application are also hereby incorporated by reference in their entirety.

### REFERENCES

[1]. Nonimaging Fresnel Lenses: Design and Performance of Solar Concentrators (Springer Series in Optical Sciences, By Ralf Leutz and A. Suzuki ISBN-13: 978-3540418412

1. A focusing polymer foil for use in an optical element for solar concentrator, which comprises a layer of switchable adhesive and a refractive lens layer.

2. A focusing polymer foil according to claim 1, wherein the switchable adhesive layer is an adhesive that can be made less adhesive by exposure to heat, pressure and/or a solvent.

3. A focusing polymer foil according to claim 1 or claim 2, wherein the refractive lens layer comprises a Fresnel lens.

4. A focusing polymer foil according to claim 3, wherein the Fresnel lens comprises Fresnel microstructures.

5. A focusing polymer foil according to claim 5, wherein the focusing polymer layer comprises Fresnel microstructures arranged in a linear, radial or concentric pattern.

6. A focusing polymer foil according to any one of claims 1 to 5, further comprising a UV stabilizer.

7. A focusing polymer foil according any one of claims 1 to 5, not comprising a UV stabilizer.

8. A focusing polymer foil according to any one of claims 1 to 7, wherein the focusing polymer foil further comprises a reflective layer, preferably a metal layer, such as a silver layer or an aluminium layer.

9. A focusing polymer foil according to claim 8, wherein the refractive lens layer comprises Fresnel microstructures, and wherein the reflective layer is formed the Fresnel microstructures.

10. A focusing polymer foil according to any one of claims 1 to 9, wherein a protective layer is formed on the reflective layer, which protective layer suitably protects the reflective layer from oxidation humidity and/or mechanical damage.

11. A focusing polymer foil according to any one of claims 1 to 10, wherein the focusing polymer foil is flexible, more preferably capable of being rolled.

12. A focusing polymer foil according to any one of claims 1 to 11, wherein the thickness of the said focusing polymer foil is less than 200 μm, more preferably less than 100 μm, even more preferably less than 50 μm and most preferably less than 30 μm.

13. A focusing polymer foil according to any one of claims 1 to 12, wherein an antireflective coating is formed on the focusing polymer foil.

14. An optical element for use as a solar concentrator, comprising:
a substrate capable of transmitting light therethrough and having a front side intended to face the sun in use and a back side intended to face away from the sun in use, and
a focusing polymer foil which comprises a refractive lens layer and a layer of switchable adhesive,
wherein the layer of switchable adhesive adheres the focusing polymer foil to the back side of the substrate.

15. An optical element according to claim 14, wherein the refractive lens layer is a microstructured refractive lens layer, preferably a Fresnel lens layer, suitably in the form of Fresnel microstructures.

16. An optical element according to claim 14 or 15, wherein the focusing polymer foil further comprises a reflective layer, preferably a metal layer, such as a silver layer or an aluminium layer.

17. An optical element according to claim 16, wherein, where the focusing polymer foil comprises Fresnel microstructures and a reflective layer, the reflective layer is formed on the Fresnel microstructures.

18. An optical element according to claim 16 or claim 17, wherein a protective layer is formed on the reflective layer, which protective layer suitably protects the reflective layer from oxidation, humidity and/or mechanical damage.

19. An optical element according to any one of claims 14 to 18, wherein the switchable adhesive is one whose adhesion is reduced by application of heat, a solvent, pressure or delaminating force, or a combination thereof.

20. An optical element according to any one of claims 14 to 19, wherein the substrate is planar.

21. An optical element according to any one of claims 14 to 20, wherein the substrate is mechanically rigid.

22. An optical element according to any one of claims 14 to 21, wherein the substrate is glass.

23. An optical element according to any one of claims 14 to 22, wherein the focusing polymer foil is in accordance with any one of claims 1 to 12.

24. An optical element according to any one of claims 14 to 23, wherein the weight per area of said focusing polymer foil to that of said substrate is less than 5%, more preferably 3%, even more preferably less than 2%, even more preferably less than 1%, and even more preferably less than 0.5% and most preferably less than 0.2%.

25. A method of repairing an optical element for use as a solar concentrator, the method comprising:
providing a damaged optical element for repair, comprising a substrate and a damaged focusing polymer foil which comprises a refractive lens layer and a layer of switchable adhesive, wherein the layer of switchable adhesive adheres the damaged focusing polymer foil to the substrate;
applying conditions to the damaged optical element that reduce the adhesion of the damaged focusing polymer foil to the substrate;
removing the damaged focusing polymer foil from the substrate;
providing a replacement focusing polymer foil comprising a refractive lens layer and a layer of switchable adhesive;
applying the switchable adhesive layer to the substrate such that the replacement focusing polymer foil is adhered to the substrate by the layer of switchable adhesive;
thus forming a repaired optical element.

26. A method according to claim 25, wherein the replacement focusing polymer foil is a focusing polymer foil according to any one of claims 1 to 13, and/or the damaged focusing polymer foil is a focusing polymer foil according to any one of claims 1 to 13, and/or the repaired optical element is an optical element according to any one of claims 14 to 24, and/or the damaged optical element is an optical element according to any one of claims 14 to 24.

27. A method according to claim 25 or claim 26, wherein the conditions applied to the damaged focusing polymer foil to reduce its adhesion to the substrate are selected from the group consisting of: heat, one or more solvents, pressure, delaminating force, or a combination of two or more thereof.

28. A method according to any one of claims 25 to 27, wherein the switchable adhesive, under the conditions applied to the damaged focusing polymer foil to reduce its adhesion to the substrate, adheres more strongly to the damaged focusing polymer foil than to the substrate.

29. A method according to any one of claims 25 to 28, wherein removal of the damaged focusing polymer foil from the substrate is performed by peeling the damaged focusing polymer foil from the substrate.

30. A method according to any one of claims 25 to 29, wherein the method further comprises the step of cleaning the substrate after removal of the damaged focusing polymer foil therefrom and before application of the replacement polymer foil.

31. A method of manufacturing a focusing polymer foil for use in an optical element for a solar concentrator, the method comprising:
forming a polymer film melt;
laminating the polymer film melt to a carrier foil while applying structuring to the polymer film melt in the form of Fresnel lens microstructures;
optionally metallizing the structured polymer film;
applying a layer of switchable adhesive to the optionally metallized structured polymer film.

32. A method of manufacturing an optical element for use in a solar concentrator, the method comprising:
providing a focusing polymer foil according to any one of claims 1 to 13, optionally manufactured according to the method of claim 31;
providing a substrate;
applying the switchable adhesive layer of the focusing polymer foil to the substrate such that the focusing polymer foil is adhered to the substrate by the layer of switchable adhesive.
